(19) United States
(12) Patent Application Publication
(10) Pub. No.: US 2025/0347504 A1
(43) Pub. Date: Nov. 13, 2025

(54) Method and System for Provision of Position Information of an Object in a Magnetic Stray Field

(71) Applicant: Siemens Healthineers AG, Forchheim (DE)

(72) Inventor: Johann Sukkau, Herzogenaurach (DE)

(73) Assignee: Siemens Healthineers AG, Forchheim (DE)

(21) Appl. No.: 19/195,900

(22) Filed: May 1, 2025

(30) Foreign Application Priority Data
May 7, 2024 (EP) 24174548.8

(51) Int. Cl. G01B 7/004; G01R 33/30

(52) U.S. Cl. CPC G01B 7/004; G01R 33/307

(57) ABSTRACT

The disclosure relates to providing position information of an object with a three-dimensional magnetic field strength sensor in the context of an apparatus generating a magnetic stray field. B0 reference data of the magnetic stray field at least in a first spatial direction is provided, with the first spatial direction being orthogonal to a second spatial direction and a third spatial direction. The B0 reference data is provided in the first spatial direction at a predefined position in the second spatial direction and the third spatial direction. The magnetic field strength sensor of the object is arranged at the predefined position; a measured value of the magnetic field strength sensor at the predefined position is provided, and position information of the object in the first spatial direction based on the B0 reference data and the measured value is also provided.

### CROSS-REFERENCE TO RELATED APPLICATIONS

The present application claims priority to and the benefit of European patent application no. EP 24174548.8, filed on May 7, 2024, the contents of which are incorporated herein by reference in their entirety.

### TECHNICAL FIELD

The present disclosure relates to a method and to a system for provision of position information of an object with a three-dimensional magnetic field strength sensor in the context of an apparatus generating a magnetic stray field.

### BACKGROUND

An apparatus generating a magnetic stray field can involve a Magnetic Resonance tomograph (MRT). Magnetic resonance tomographs are imaging apparatuses that, for imaging an examination object, align nuclear spins of the examination object with a strong external magnetic field and excite them into precession about these alignments by means of a magnetic alternating field. The precession or return of the spins from this excited state into a state with lower energy in its turn generates a magnetic alternating field as a response, which is received via antennas.

A spatial encoding is impressed upon the signals with the aid of magnetic gradient fields, which subsequently make possible an assignment of the received signal to a volume element. The received signal is then evaluated and a three-dimensional imaging representation of the examination object is provided.

Usually the spatial encoding is based on an X-Y-Z coordinate system. In this system, the Z coordinate axis is usually defined as an axis of symmetry of a B0 field magnet of the magnetic resonance tomograph through a patient tunnel of the B0 field magnet in the preferred direction of the B0 field. The Z coordinate axis is usually aligned horizontally in a typical arrangement of a magnetic resonance tomograph, and runs centrally through the opening of the windings of the B0 field magnet through a recording area of the B0 field magnet. The object to be imaged is usually placed parallel to the Z coordinate axis on a patient couch in the patient tunnel. Together with the Z coordinate axis, an X coordinate axis and a Y coordinate axis span a space, with the coordinate axes generally being provided orthogonal to one another, with the X coordinate axis being aligned horizontally and the Y coordinate axis vertically.

In the context of such a magnetic resonance tomograph, there can be a wide diversity of applications in which determining a position of an object is required. Objects such as patient couches with controllable adjustments or movement facilities may, for example, be activated and moved autonomously based on such position information. One possible application of such a patient couch may be to lower the patient couch slightly so that a patient can lie comfortably on the couch surface. Subsequently, the couch is moved back up again and aligned relative to the patient tunnel, which is also referred to as the bore. After the patient couch has been aligned accordingly, the patient may be moved into the patient tunnel on the patient couch.

For alignment of the patient couch relative to the patient tunnel in this way, it is known for example that a reflector element can be fitted to the magnetic resonance tomograph at a predefined position relative to the middle of the B0 magnet. Corresponding to this, a light source and a photodiode are likewise arranged on the patient couch at a pre-defined position. The light source is aligned in this case in such a way that the light source can emit light onto the reflector element as soon as the two are aligned corresponding to one another. The light reflected back by the reflector element can then be detected exclusively by the photodiode. When the patient couch is moved upwards from the lowered position below the patient tunnel, the speed of movement of the patient couch is reduced as soon as the start of the reflector element is detected by the photodiode. The patient couch is then moved further upwards slowly until the upper edge of the reflector element has been detected. The upper edge of the reflector element is arranged in such a way in this case that the patient couch is aligned relative to the patient tunnel or to the B0 magnet and the patient couch can be moved into the patient tunnel. However, this procedure requires a comparatively large amount of time, since the patient couch needs to be moved upwards slowly from the detection of the reflector element to be reliably detect the upper edge of the reflector element. Additionally, attaching the reflector element during the installation of the magnetic resonance tomograph requires a comparatively large amount of time, since the reflector element must be arranged with great care.

### SUMMARY

In this context, there is a need for providing a method and a system with which position information of an object can be provided with a three-dimensional magnetic field strength sensor in the context of an apparatus generating a magnetic stray field. For instance, there is a need to simplify an alignment of a patient couch of a magnetic resonance tomograph relative to a patient tunnel or relative to a B0 magnet of a magnetic resonance tomograph.

It is therefore an object of the present disclosure to provide a method and a system with which position information of an object can be provided with a three-dimensional magnetic field strength sensor in the context of an apparatus generating a magnetic stray field. For example, an object of the present disclosure is to simplify an alignment of a patient couch of a magnetic resonance tomograph relative to a patient tunnel or to a B0 magnet magnetic resonance tomograph.

These and other objects, which are still to be mentioned when reading this description or will be recognized by the person skilled in the art, are achieved by the subject matter of the embodiments as discussed herein, including those described in the claims.

In accordance with the disclosure, a method for provision of position information of an object with a three-dimensional magnetic field strength sensor in the context of an apparatus generating a magnetic stray field is described, wherein the method comprises at least the following steps:

Provision of B0 reference data of the magnetic stray field at least in a first spatial direction (DCS.Y), wherein the first spatial direction (DCS.Y) is provided orthogonal to a second spatial direction (DCS.X) and a third spatial direction (DCS.Z), and wherein the B0 reference data in the first spatial direction (DCS.Y) is provided at a predefined position in the second spatial direction (DCS.Z) and the third spatial direction (DCS.X);

Arrangement of the magnetic field strength sensor on the object at the predefined position;

Provision of a measured value of the magnetic field strength sensor at the predefined position;

Provision of position information of the object in the first spatial direction (DCS.Y) based on the B0 reference data and the measured value.

In an embodiment, the first spatial direction corresponds to the Y coordinate axis, the second spatial direction to the Y coordinate axis, and the third spatial direction to the Z coordinate axis. In this case, the Z coordinate axis may be e.g. defined as an axis of symmetry of the B0 field magnet of the magnetic resonance tomograph through the patient tunnel of the B0 field magnet in the preferred direction of the B0 field. The Z coordinate axis in this case may be e.g. aligned horizontally and run centrally through the opening of the windings of the B0 field magnet through the receiving area of the B0 field magnet. The coordinate axes are provided orthogonal to one another, wherein the X coordinate axis is aligned horizontally and the Y coordinate axis vertically. Such a coordinate system aligned on the B0 field magnet is referred to in practice as the so-called “Device Coordinate System” (DCS).

In other words, the present disclosure proposes that B0 reference data of the magnetic stray field be provided along the vertical Y coordinate axis at a predefined position in the horizontal X-Z coordinate plane. At this predefined position, for example a three-dimensional magnetic field strength sensor may be arranged on a height-adjustable patient couch in the X-Z coordinate plane so that, with the aid of the B0 reference data and the measured values of the magnetic field strength sensor, the position of the magnetic field strength sensor along the vertical Y coordinate axis can be established. This provides the possibility of determining the position of the magnetic field strength sensor relative to the patient receiving area along the Y coordinate axis. In the vertical alignment of the Y coordinate axis, the possibility thus exists for including the position information of the magnetic field strength sensor along the Y coordinate axis for alignment of the patient couch relative to the patient receiving area or relative to the B0 magnet.

A method is thus disclosed as to how, with the aid of a three-dimensional magnetic field strength sensor, a vertical Y coordinate of a patient couch may be established from the B0 field, wherein the Y coordinate can be immediately established directly after the magnetic field strength sensor is switched on. Thus, a patient may begin lying in a lowered position on the couch and, as soon as the patient is lying on the patient couch, the patient couch can be raised again. Through this, the patient couch may be moved comparatively rapidly back into a position aligned with the B0 magnet. Additionally, the time-consuming positioning of a reflector element and of a corresponding light source and photodiode during an installation of a magnetic resonance tomograph is not necessary.

As already stated, the object may for instance comprise a patient couch, which may be embodied height-adjustable at least in the first spatial direction (DCS.Y), and wherein the magnetic stray field may be generated by a magnetic resonance tomograph.

In an embodiment, the magnetic field strength sensor is arranged in a corner area of the patient couch, and the magnetic field strength sensor may e.g. be arranged on an upper edge of the patient couch. This positioning of the at least one magnetic field strength sensor enables said sensor to be arranged in a preferred area of the B0 magnetic field, at which the magnetic field strength sensor is configured to detect a field strength of three components of the B0 field in three directions, which span a space, and the magnetic field strength sensor establishes the magnetic field strength as an amount of a B0 field vector determined by the three components of the B0 field.

In an embodiment, the B0 reference data is provided in the first spatial directions (DCS.Y) only for a predefined area. In a coordinate system (DCS coordinate system) aligned to the B0 field magnet, the predefined area may have a Y coordinate axis (DCS.Y) between any suitable range of values, such as for instance between −700 and 0 mm, between −600 and 30 mm, between −550 and 15 mm, etc.

In an embodiment, the B0 reference data is provided in the first spatial direction (DCS.Y) in grid points with any suitable resolution, such as for instance a resolution between 0.1 and 10 mm, between 0.5 and 2 mm, between 0.7 and 1.5 mm, a resolution of 1 mm, etc.

In an embodiment, the stray field information is provided between two adjacent grid points by interpolation, e.g. by a linear interpolation or by a spline interpolation.

In an embodiment, the position information of the object in the first spatial direction (DCS.Y) is established by comparison of the measured value with the B0 reference data, wherein the position information is established in a first area by comparing an amount of the measured value components in the three spatial directions with the B0 reference data; the position information is established in a second area by comparing an amount of a measured value component in the second spatial direction (DCS.Z) or by comparing the amount of the measured value components in the three spatial directions with the B0 reference data; and the position information is established in a third area by comparing a measured value component in the first spatial direction (DCS.Y) with the B0 reference data.

In an embodiment, the three-dimensional magnetic field strength sensor is arranged on the object in such a way that the axes of the three-dimensional magnetic field strength sensor are aligned collinearly to the three spatial directions (DCS.X, DCS.Y, DCS.Z) of the magnetic stray field.

In an embodiment, the object further comprises at least one memory means, in which at least the B0 reference data in the first spatial direction (DCS.Y) is stored.

In an embodiment, the object further comprises at least one computation means, which is configured to provide the position information of the object.

In an embodiment, the method further comprises the following steps:

Provision of a correction factor based on a resonant frequency of the apparatus generating a magnetic stray field, e.g. of the magnetic resonance tomograph; and adaptation of the B0 reference data of the magnetic stray field based on the correction factor.

In an embodiment, the method further comprises the following step:

Provision of control data for a movement facility, which is configured to move at least a part of the object, wherein the control data is based on the position information of the object provided in the first spatial direction (DCS.Y).

The present disclosure further relates to a system for provision of position information of an object with a three-dimensional magnetic field strength sensor in the context of an apparatus generating a magnetic stray field, comprising:

A first interface, configured to receive B0 reference data of the magnetic stray field at least in a first spatial direction (DCS.Y), wherein the first spatial direction (DCS.Y) is provided orthogonal to a second spatial direction (DCS.X) and a third spatial direction (DCS.Z), and wherein the B0 reference data is provided in the first spatial direction (DCS.Y) at a predefined position in the second spatial direction (DCS.Z) and the third spatial direction (DCS.X);
a second interface, configured to receive a measured value of the magnetic field strength sensor at the predefined position;
a processing unit, which is connected to the interfaces and is configured to carry out the method described above, for provision of position information of an object with a three-dimensional magnetic field strength sensor in the context of an apparatus generating a magnetic stray field.

Finally the present disclosure relates to use of a patient couch configured to be height-adjustable in a first spatial direction (DCS.Y) with at least one three-dimensional magnetic field strength sensor in a method described above for provision of position information of an object with a three-dimensional magnetic field strength sensor in the context of an apparatus generating a magnetic stray field.

### BRIEF DESCRIPTION OF THE DRAWINGS

Any embodiments described herein may be combined with one another, unless explicitly stated otherwise. Further features, advantages, and possible applications of the present disclosure emerge from the description given below, the exemplary emB0diment and the figures.

In the figures:

FIG. 1 illustrates a plan view of an example system for provision of position information of an object with a three-dimensional magnetic field strength sensor in the context of an apparatus, in the form of a magnetic resonance tomograph, generating a magnetic stray field, in accordance with the disclosure;

FIG. 2 illustrates a side view of the example magnetic resonance tomograph shown in FIG. 1, in accordance with the disclosure;

FIG. 3 illustrates a schematic diagram of an example method for providing position information of an object with a three-dimensional magnetic field strength sensor in the context of an apparatus generating a magnetic stray field, in accordance with the disclosure; and

FIG. 4 illustrates an example course of |B0|, B0. Y, B0.Z along a vertical direction at a predefined position for a B0 magnet that generates 1.5 Tesla, in accordance with the disclosure.

### DETAILED DESCRIPTION OF THE DISCLOSURE

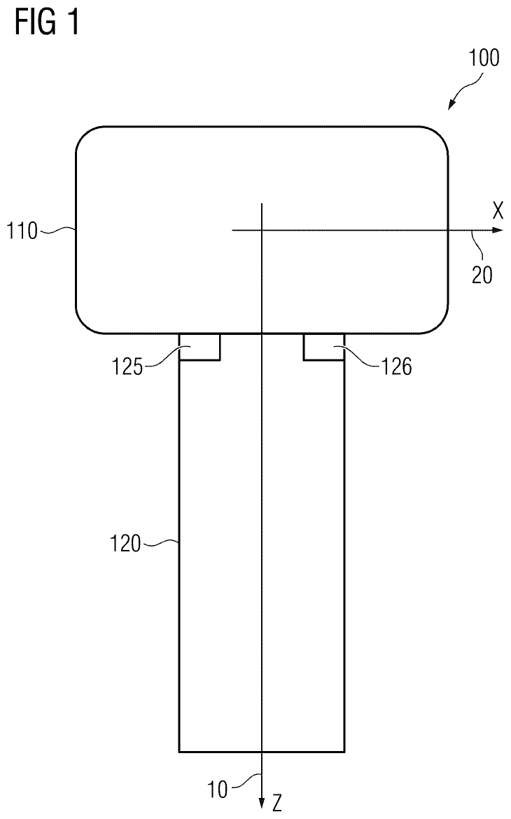

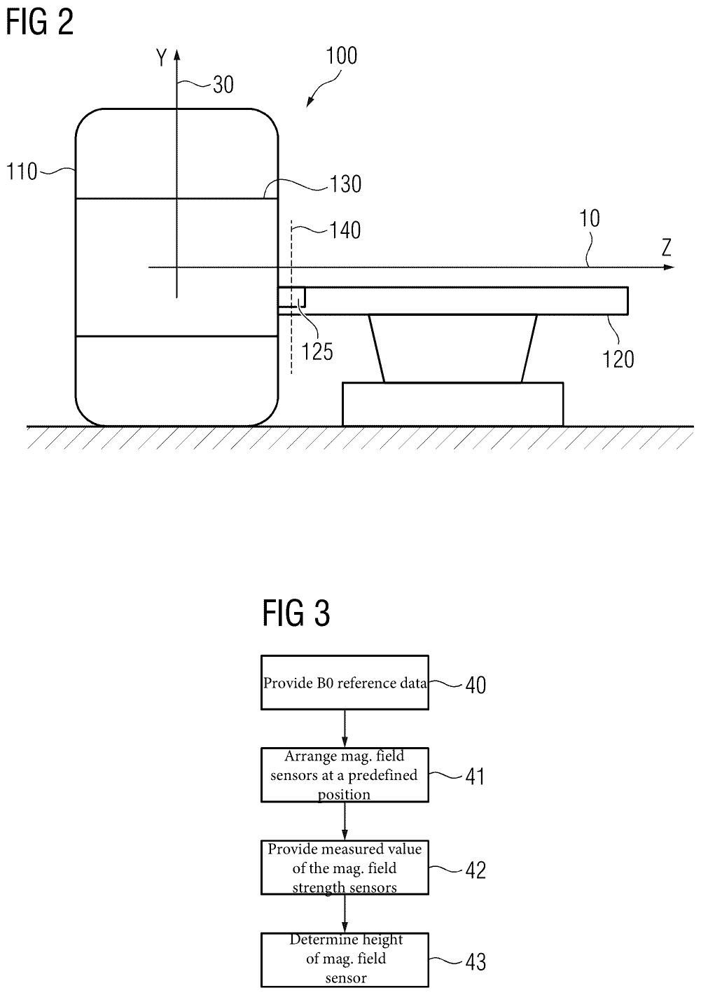

FIG. 1 illustrates a plan view of an example system for provision of position information of an object with a three-dimensional magnetic field strength sensor in the context of an apparatus, in the form of a magnetic resonance tomograph, generating a magnetic stray field, in accordance with the disclosure. Specifically, FIG. 1 shows a plan view and FIG. 2 a side view of an example system 100, in the form of a magnetic resonance tomograph 100. The magnetic resonance tomograph 100 comprises a B0 field magnet 110 and a patient couch 120.

As is shown in FIGS. 1 and 2, the spatial encoding is based on an X-Y-Z coordinate system. In this system, the Z coordinate axis 10 is defined as usual as an axis of symmetry of the B0 field magnet 110 through a patient tunnel 130 of the B0 field magnet 110 in the preferred direction of the B0 field. The Z coordinate axis 10, with the usual positioning of the magnetic resonance tomograph 100 shown, is aligned horizontally and runs centrally through the opening of the windings of the B0 field magnet 110 through the patient tunnel 130 of the B0 field magnet 110. The object to be imaged is usually brought on the patient couch 120 into the patient tunnel 130 in parallel to the Z coordinate axis 10. Together with the Z coordinate axis 10, an X coordinate axis 20 and a Y coordinate axis 30 span a space, wherein the X-Y-Z coordinate axes may be e.g. provided orthogonal to one another, and wherein the X coordinate axis is aligned horizontally and the Y coordinate axis is aligned vertically.

As shown in FIGS. 1 and 2, the patient couch 120 comprises two three-dimensional magnetic field strength sensors 125, 126. The magnetic field strength sensors 125, 126 are configured to detect a field strength of three components of the B0 field in three directions that span a space, and the magnetic field strength sensor determines the magnetic field strength as an amount of a B0 field vector determined by the three components of the B0 field. In an embodiment, the axes of the three-dimensional magnetic field strength sensor 125, 126 are aligned collinearly to the X-Y-Z coordinate axes.

To carry out the method, at least one of the magnetic field strength sensors 125, 126, may be provided e.g. at one of the front corners of the patient couch 120. More than one magnetic field strength sensor 125, 126 can also be provided. As shown in the exemplary embodiment, magnetic field strength sensors 125, 126 can be provided for example at the two front corner areas of the patient couch 120.

The present disclosure is not restricted in this case to a specific number of magnetic field strength sensors 125, 126. The present disclosure is also not restricted to the magnetic field strength sensors 125, 126 being arranged at a specific position of the patient couch 120. However, it may be particularly advantageous to have the magnetic field strength sensors 125, 126 arranged at the front corners of the patient couch 120 or in the front corner area of the patient couch 120. For instance, the magnetic field strength sensors 125, 126 may be provided directly on the left edge of the couch or the right edge of the couch, as is shown for example in FIGS. 1 and 2.

In an embodiment, the magnetic field strength sensors 125, 126 and, optionally, a corresponding microcontroller that may be provided for processing and evaluating the measurement data, may be surrounded by any suitable shied such as a MR-protected Faraday cage, which may be made of woven carbon fiber, for example. This enables disruptive image artifacts to be avoided during a measurement and ensures that the magnetic field strength sensors 125, 126 (and, when present, the corresponding microcontroller itself) are not destroyed. In this regard, the possibility also exists for switching off the magnetic field strength sensors 125, 126 during a measurement. In an embodiment, data is transmitted to the scanner or to a higher-ranking couch controller by an electrical and/or an optical transmission path and/or by wireless transmission.

FIG. 3 illustrates a schematic diagram of an example method for providing position information of an object with a three-dimensional magnetic field strength sensor in the context of an apparatus generating a magnetic stray field, in accordance with the disclosure. Specifically, FIG. 3 shows a schematic diagram of a method for provision of position information of an object with a three-dimensional magnetic field strength sensor in the context of an apparatus generating a magnetic stray field.

In a first step 40, B0 reference data of the magnetic stray field is provided (e.g. received, stored, calculated, etc.) at least in a first spatial direction. This may then be referred back to in the determination of the position-or location of the magnetic field strength sensors 125, 126.

The B0 reference data is provided by the field distribution of the B0 magnetic field in the three-dimensional space. This means that for a specific point in the X-Y-Z coordinate system, a B0 vector with the three parameters (B0.X, B0.Y, B0.Z) and an amount |B0| are provided.

The first spatial direction is provided orthogonal to a second spatial direction and a third spatial direction, wherein the B0 reference data is provided in the first spatial direction at a predefined position in the second spatial direction and the third spatial direction. The first spatial direction may e.g. be provided in parallel to the Y coordinate axis, wherein B0 reference data may e.g. be only provided for an area or a distance that corresponds to the adjustability of the height of the patient couch 120. In an exemplary embodiment, two magnetic field strength sensors 125, 126 are provided in the front corner areas of the patient couch 120. Corresponding to this B0 reference data is provided in the first spatial direction at two predefined positions in the X-Z coordinate plane. In FIG. 2, the area that corresponds to the height adjustability of the patient couch 120 is indicated by the dashed line 140. In an embodiment, only B0 reference data that corresponds to the height adjustability of the patient couch 120 may be provided in the first spatial direction, i.e. only along the dashed line 140.

In a further step 41, the magnetic field strength sensors 125, 126 of the object, here the patient couch 120, are arranged at the predefined position. In other words, the patient couch 120 may be positioned on the B0 magnet 110 in such a way that the magnetic field strength sensors 125, 126 of the patient couch 120 are each arranged at the position for which the B0 reference data has been provided in the first spatial direction. As can be readily seen in FIG. 2, the magnetic field strength sensor 125 may e.g. be positioned on the dashed line 140. In a height adjustment of the patient couch 120, the magnetic field strength sensor 125 moves along the dashed line 140, i.e. in parallel to the Y coordinate axis, and thus along the area for which the B0 reference data in the first spatial direction has been provided.

In a further step 42, a measured value of the magnetic field strength sensor 125, 126 is provided (e.g. received, stored, calculated, etc.). In a further step 43, the height or the Y coordinate of the magnetic field strength sensor 125, 126 in its respective position on the dashed line 140 can be established by finally comparing the measured value and the B0 reference data.

In other words, the present disclosure proposes providing B0 reference data of the magnetic stray field in parallel to the vertical Y coordinate axis at a predefined position in the horizontal X-Z coordinate plane. At this predefined position, the magnetic field strength sensor 125, 126 arranged on the height-adjustable patient couch 120 may be arranged in the X-Z coordinate plane, so that, with the aid of the B0 reference data and the measured values of the magnetic field strength sensors 125, 126, the position of the magnetic field strength sensors can be established. This provides the possibility of enabling the position of the magnetic field strength sensor 125, 126 relative to the patient receiving area 130 along the Y coordinate axis to be determined. In e.g. a vertical alignment of the Y coordinate axis, there thus exists the possibility of including the position information of the magnetic field strength sensor 125, 126 along the Y coordinate axis for alignment of the patient couch 120 relative to the patient receiving area 130 or relative to the B0 magnet 110.

Further embodiments and aspects of the method are described in further detail below.

The necessary B0 reference data may e.g. be heavily spatially restricted for the present use, since B0 reference data is only required on a vertical from the floor of the scanner space up to a maximum of the middle of the B0 magnet 110, as the magnetic field strength sensors 125, 126 may be positioned in this area due to the limited height adjustability of the patient couch 120. If, for example, B0 reference data is provided along the vertical with a 1 mm sampling, 1000 B0 reference values would need to be detected and provided for a vertical of 1 meter. The X coordinate and the Z coordinate are fixed by the geometry of the B0 magnet and the patient couch 120. In an embodiment, one of the magnetic field strength sensors 125, 126 is located to the front right on the patient couch 120, for example at an X coordinate of 300 mm and a Z coordinate of 800 mm. The second magnetic field strength sensor 125 is also located to the front left of the patient couch 120, for example at an X coordinate of −300 mm and a Z coordinate of 800 mm. The vertical lines 140 corresponding to this (cf. FIG. 2) with these coordinates are located just outside the B0 magnet 110 in the corners of the docked patient couch 120.

This restriction of the B0 reference data to 1000 values makes it possible for the present method of establishing a Y position/coordinate of a magnetic field strength sensor 125, 126 or of a patient couch 120 to be carried out on a less powerful microcontroller with comparatively few memory means. The resolution of the B0 reference data of 1 mm does not mean in this case, however, that the accuracy of the position determination would be restricted to a 1 mm resolution. Since the B0 field courses are embodied steady and smooth, these may be well approximated between two neighboring B0 reference data points by a linear interpolation. The B0 reference data to be provided may be further restricted in this case by account being taken of the patient couch 120 not being able to be moved right to the bottom of the scanner space, but typically having a lowest setting at a minimum height of around 57 cm from the floor. It is this possible thus to only provide B0 reference data as from a minimal height of a patient couch 120.

In order to carry out the Y position determination from the B0 reference data in the most optimal form possible, the position information may e.g. be derived in different Y coordinate areas by comparison of different measured value components. As stated, the field distribution of the B0 magnetic field in the three-dimensional space is provided by the B0 reference data. That means that, for a specific point in the X-Y-Z coordinate system, a B0 vector with the three parameters (B0.X, B0.Y, B0.Z) and its amount |B0| is provided.

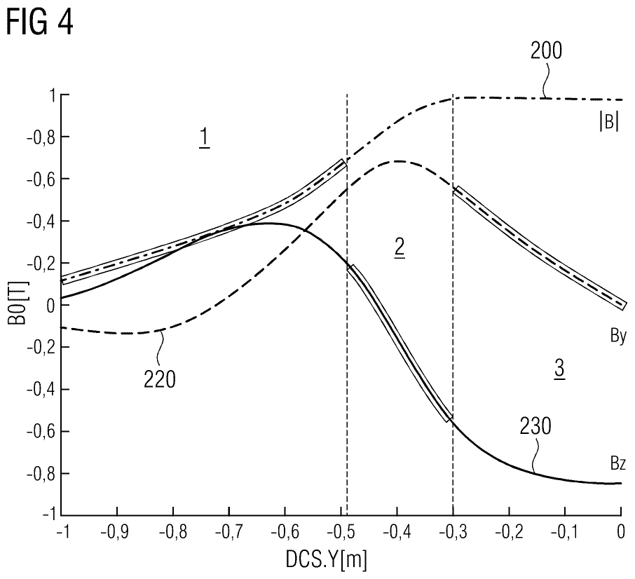

In FIG. 4, the course of |B0|, B0. Y, B0. Z along the vertical 140 is depicted for a B0 magnet that generates 1.5 tesla. The vertical 140 is provided on the front right on the patient couch 120, for example at an X coordinate of 300 mm and a Z coordinate of 800 mm. The line 200 shows the graph of the B0 amount along the vertical 140. The line 210 corresponds to the graph of B0. Y and the line 230 shows B0. Z along the vertical 140.

The position of a magnetic field strength sensor 125 in the X-Y plane with the values X=300 mm and Z=800 mm given here by way of example relates to a 1.6 m long B0 field magnet given by way of example. The 3 Tesla B0 field magnets may be somewhat longer, for example 1.9 m, and the 7 Tesla B0 field magnets may again be somewhat longer. With this length, the Z position changes correspondingly, for example to Z=950 mm. The X position is dependent of the diameter of the patient tunnel 130. The corresponding coordinates may e.g. be selected in such a way that a magnetic field strength sensor is advantageous fitted where possible on the left or right edge of the patient couch 120, since there the B0 reference data runs especially advantageously. However, the present disclosure is not restricted to such an arrangement, since the present disclosure may also be carried out on any other given X-Z coordinates of the patient couch 120.

For other B0 magnets frequently employed in practice, for example with 0.55 tesla, 3 tesla or 7 tesla, the course of |B0|, B0.Y, B0.Z may be embodied similarly, as these essentially differ only by scaling factors. The course shown in FIG. 4 for |B0|, B0.Y, B0.Z can thus be considered to be representative of other B0 magnetic fields.

As can be readily seen in FIG. 4, the areas identified by “1,” “2,” and “3” each lead, with a different comparison of the measured value of the magnetic field strength sensors 125, 126 with |B0|, B0.Y or B0.Z, to unique or more accurate results for the Y coordinate.

For example in area “3”, i.e. for DCS.Y >−0.3 m, the determination of the Y coordinate from |B0| is not carried out very precisely, since the course |B0| in area “3” is almost horizontal and a determination of a Y coordinate from a B0 amount measured by the magnetic field strength sensor 125, 126 would thus not produce a defined/small point in the Y direction, but a comparatively large Y area. In the area “2”, i.e. at −0.5 m <DCS.Y <−0.3 m, a determination of a Y coordinate from the B0 amount, although basically possible, would not be optimal however, on account of an incline in the direction of the area “3” becoming ever flatter. The course of the B0 amount in area “1” is optimal on the other hand, since this runs almost linearly and strictly monotonously rising. The other two courses Bz and By likewise do not lead in area “1” to any exact Y coordinate, but to a Y area, i.e. to a comparatively imprecise Y position determination.

In area “2,” the Y coordinate may be determined both from |B|, and also from Bz with high accuracy. The determination from Bz can lead to even more precise Y coordinates, since in area “2” the Bz incline is markedly higher and the course of Bz is falling strictly monotonously and is nearly linear.

In area “3,” the Y coordinate may be determined with high accuracy from By, of which the course there is falling strictly monotonously.

Thus, in an embodiment, for the Y position determination of the magnetic field strength sensors 125, 126 or of the patient couch 120:
the Y position determination is undertaken in a first area of the vertical 140 by comparison of the |B0| reference data with the |B0| measured value components;
the Y position information is determined in a second area of the vertical 140 by comparison of the Bz reference data or |B0| reference data with the respective measured value components; and
the Y position information is determined in a third area of the vertical 140 by comparison of the By reference data with the By measured value components.

The actual computation of the Y coordinate of one of the magnetic field strength sensors 125, 126 may e.g. be undertaken in two steps. In a first step, the two neighboring values from the B0 reference data are first established, which include the measured value of the magnetic field strength sensor 125, 126. In a second step, there is an interpolation of the two neighboring values from the B0 reference data, so that the Y coordinate for the measured value of the magnetic field strength sensors 125, 126 can be established more precisely. Such interpolation can be embodied as any suitable approximations such as for instance linear interpolation or also as a spline interpolation.

With the proposed method, the Y coordinate or the Y position of a patient couch 120 may be determined comparatively precisely, in practice with an accuracy of around 0.1 mm, and at a comparatively low cost. By contrast, as was the case with previous procedures, time-consuming alignments to a retro reflector element are no longer necessary. The Y coordinate of the patient couch 120 may be provided instantaneously, excepting for processing latencies. Also, the installation of a magnetic resonance tomograph may be undertaken more quickly, since a retro reflector element no longer has to be provided on the B0 magnet 110, and thus time-consuming adjustment is no longer necessary.

The present disclosure is not restricted to the form of embodiment described above, as long as said form is covered by the subject matter of the claims given below. In addition it is pointed out that the terms “comprising” and “having” do not exclude any other elements and steps, and the indefinite article “a” or “an” does not exclude a plurality. It is further pointed out that features or steps that have been described with reference to above forms of embodiment can also be used in combination with other features.

Above and beyond this it is pointed out that, independent of the grammatical term usage, individuals with male, female or other gender identities are included within the term.

The various components described herein may be referred to as “units.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such units, as applicable and relevant, may alternatively be referred to herein as “circuitry,” “controllers,” “processors,” or “processing circuitry,” or alternatively as noted herein.

What is claimed is:

1. A method for providing, using a three-dimensional (3D) magnetic field strength sensor, position information of an object with respect to an apparatus generating a magnetic stray field, the method comprising:
providing B0 reference data of the magnetic stray field in a first spatial direction, the first spatial direction being orthogonal to a second spatial direction and a to third spatial direction, and the B0 reference data being provided in the first spatial direction at a predefined position in the second spatial direction and the third spatial direction;
arranging the 3D magnetic field strength sensor at the predefined position;
providing a measured value of the 3D magnetic field strength sensor at the predefined position; and
providing the position information of the object in the first spatial direction based on the B0 reference data and the measured value.

2. The method as claimed in claim 1, wherein the object comprises a patient couch configured to be height-adjustable in the first spatial direction, and
wherein the magnetic stray field is generated via a magnetic resonance tomograph.

3. The method as claimed in claim 2, wherein the 3D magnetic field strength sensor is arranged at a corner region of the patient couch, and
wherein the 3D magnetic field strength sensor is arranged on an upper edge of the patient couch.

4. The method as claimed in claim 2, wherein the B0 reference data is provided in the first spatial directions only for a predefined area that corresponds to an area of height adjustability of the patient couch.

5. The method as claimed in claim 4, wherein the predefined area, in a Device Coordinate System (DCS), is aligned to a B0 field magnet and has a Y coordinate axis between −700 and 0 mm.

6. The method as claimed in claim 1, wherein the B0 reference data is provided in the first spatial direction in grid points with a resolution between 0.1 and 10 mm.

7. The method as claimed in claim 1, wherein the B0 reference data is provided in the first spatial direction in grid points with a resolution between 0.5 and 2 mm.

8. The method as claimed in claim 1, wherein the B0 reference data is provided in the first spatial direction in grid points with a resolution between 0.7 and 1.5 mm.

9. The method as claimed in claim 1, wherein the B0 reference data is provided in the first spatial direction in grid points with a resolution of 1 mm.

10. The method as claimed in claim 1, wherein stray field information is provided between two neighboring grid points via linear interpolation or via spline interpolation.

11. The method as claimed in claim 1, wherein:
the position information of the object is established in the first spatial direction by comparison of the measured value with the B0 reference data,
the position information in a first area is established by comparison of an amount of measured value components in the first, second, and third spatial directions with the B0 reference data;
the position information in a second area is established by comparison of an amount of a measured value component in the third spatial direction; and
the position information in a third area is established by comparison of an amount of a measured value component in the first spatial direction with the B0 reference data.

12. The method as claimed in claim 1, wherein the 3D magnetic field strength sensor is arranged on the object such that axes of the 3D magnetic field strength sensor are aligned collinearly to three respective X-Y-Z coordinate axes of the magnetic stray field.

13. The method as claimed in claim 1, wherein the object further comprises a memory means for storing the B0 reference data in the first spatial direction.

14. The method as claimed in claim 1, wherein the object further comprises a processing means for providing the position information of the object.

15. The method as claimed in claim 1, wherein the apparatus comprises a magnetic resonance tomograph that generates the magnetic stray field, and further comprising:
providing a correction factor based on a resonant frequency of the magnetic resonance tomograph; and
adapting the B0 reference data of the magnetic stray field in the first spatial direction based on the correction factor.

16. The method as claimed in claim 1, further comprising:
providing control data for a movement facility, which is configured to move at least a part of the object,
wherein the control data is based on the position information of the object in the first spatial direction.

17. A system for providing, using a three-dimensional (3D) magnetic field strength sensor, position information of an object with respect to an apparatus generating a magnetic stray field, the system comprising:
a first interface configured to receive B0 reference data of the magnetic stray field in a first spatial direction, the first spatial direction being orthogonal to a second spatial direction and a to third spatial direction, and the B0 reference data being provided in the first spatial direction at a predefined position in the second spatial direction and the third spatial direction;
a second interface configured to receive a measured value of the 3D magnetic field strength sensor at the predefined position; and
processing circuitry coupled to the first and the second interface, the processing circuitry to provide the position information of the object in the first spatial direction based on the B0 reference data and the measured value.
